(19) United States
(12) Patent Application Publication
(10) Pub. No.: US 2001/0019518 A1
(43) Pub. Date: Sep. 6, 2001

(54) Method and apparatus for reading information stored in a fluorescent multilayer information carrier

(76) Inventors: Eugene Levich, New York, NY (US); Boris Chernobrod, Rehobot (IL); Anatolii Dovgan, Lviv (UA)

Correspondence Address: BLANK ROME COMISKY & MCCAULEY LLP, THE FARRAGUT BUILDING, SUITE 1000, 900 17TH STREET, NW, WASHINGTON, DC, 20006, US

(21) Appl. No.: 09/774,873

(22) Filed: Feb. 1, 2001

(30) Foreign Application Priority Data
Feb. 3, 2000 (IL) 134358

(51) Int. Cl. G11B 7/095; G11B 7/13

(52) U.S. Cl. 369/44.13; 369/94; 369/108; 369/44.41; 369/120

(57) ABSTRACT

An apparatus and method for reproducing information stored in a fluorescent multilayer information carrier. The apparatus utilizes auto-focusing and auto-framing techniques when reading the information to enable parallel reading from uniformly moving carrier. To avoid discontinuity in motion, an actuator with an objective lens performs periodic motion following a specific moving information page and, after the end of reading of this page, returns back to follow the next page.

### FIELD OF THE INVENTION

The present invention relates to an optical reproducing apparatus for reading information from a multilayer fluorescent information carrier.

### BACKGROUND OF THE INVENTION

To date progress in the capacity of optical data storage was based on increasing planar data density associated with the application of blue and violet diode lasers and LEDs, and optics with high numerical aperture. The logic of this tendency leads to methods with sub-wavelength resolution, known as near-field optics. These methods require mechanics with nano-meter accuracy, which means completely new design and engineering of optical storage device.

Another approach to increasing data capacity based on ordinary optics is volumetric optical storage such as holography, two-photon recording and multilayer fluorescent methods. In a fluorescent in formation can, information is stored in the form of a pattern including spaced-apart pits filled by a fluorescent dye. The serious advantages of the fluorescent multilayer method are connected with its incoherent nature. The spatial optical resolution of an incoherent image is two times higher, the signal-to-noise ratio (SNR) in a fluorescent system is much higher because there is no interference noise. The fluorescent multilayer method has enormous potential for increasing the number of layers, therefore there is a possibility to obtain Gigabyte capacity in a compact carrier such as an optical card having credit card size.

### SUMMARY OF THE INVENTION

There is a need in the art to facilitate reading information from a fluorescent multilayer information carrier by providing a novel method and apparatus therefor.

According to the invention, the information recorded in a fluorescent information carrier is read by the excitation of fluorescence using a light source (diode laser or LED) and by imaging an information field onto the photosensitive matrix (i.e., the photosensitive area of a CCD or CMOS detector). The information is stored in the information carrier (e.g., an optical card) in the form of a pattern including spaced-apart pits filled by a fluorescent dye. The entire information field consists of a plurality of sub-fields or pages. The information is read by sequentially imaging successive pages onto the photosensitive matrix. The entire page is imaged by sequentially imaging successive frames thereof, defined by the geometry of an illuminated areas which is, in turn, defined by the geometry of the cross-section of the incident light beam.

The main idea of the present invention consists of utilizing auto-focusing and auto-framing techniques when reading the information to enable parallel reading, when plurality of bits are read simultaneously from a uniformly moving carrier. To avoid discontinuity in motion, an actuator with an objective lens performs periodic motion following a specific moving information page and, after the completely end reading of this page, returns back to follow the next page.

The reading of the entire information field by sequential reading of the sub-fields (pages) may be implemented either by reading all the pages in one layer and then shifting to the next layer, or by reading one column (vertically aligned pages of all the layers) and then shifting to another column. The technique of the present invention utilizes a system of excitation, an auto-focusing system, an auto-framing system and a carrier motion system.

The system of excitation is based on a scanner designed for frame-by-frame scanning of the page by a laser beam. The laser beam may have a strip-like geometry, each strip presenting the frame of a page, or a circular geometry, in which case each frame is formed by scanning the strip-like area with a small spot.

The auto-focusing system for focusing/refocusing the laser beam from layer to layer utilizes a wobbling system controlled by a servo signal from the photosensitive matrix for providing wobbling of the micro-objective along the optical axis. According to one embodiment of the invention, the actuator with micro-objective oscillates around a position of optimal focusing, which leads to the oscillation of an electrical signal from the photosensitive matrix at the same frequency. After synchrony detection, a differential signal of focus error is generated that provides feedback to the servo mover of the actuator with the objective lens. The value of the wobbling frequency ƒ is chosen such that that the frame rate F is equal to a multiple of the wobbling frequency F=N·ƒ(N=1, 2, . . . ). According to an alternative embodiment of the invention, special fluorescent marks are provided on the information carrier and are imaged on a special group of pixels of the photosensitive matrix. The wobbling frequency ƒ has the following relation with the readout rate W of this special group of pixels: W=Nƒ=1, 2, . . . ). In this embodiment, the wobbling frequency ƒ can be much higher than the frame rate F, and the time of reaction of the auto-focusing system can be shorter than in the previous embodiment. The time of refocusing from layer to layer also can be shorter in this example.

The auto-framing system is controlled by a differential servo-signal from the photosensitive matrix. In order to read information page by page, the carrier motion system provides relative displacement between an optical readout head and the information carrier within the X-Y-plane (plane parallel to the surface of the carrier). This can be implemented by moving the optical card along the X-axis, while moving the optical readout head along the Y-axis or vice versa. The optical card motion system may provide movement of the card along the X- and Y-axes, while the location of the optical readout head in the X-Y-plane is fixed or vice versa. The certain time of exposition is obtained by a step-like motion. The optical card may be mounted for uniform motion and an actuator with an objective lens of the readout head may follow a certain page for an exposition time and return back to read the next page.

The carrier motion system is aimed at providing the precise relative positioning between the carrier and the readout optical head in the XY-plane, to provide the alignment of the readout head with a specific page with proper accuracy. The alignment is such that the image of this specific page is symmetrical with respect to an axis of symmetry of the photosensitive area of the CCD matrix. The X,Y position error signal may be obtained by processing the signal from the CCD) matrix: the X position error signal is a differential signal of the upper and lower halves of the photosensitive area of the CCD matrix, and the Y position error signal is a differential signal of right and left halves of the photosensitive area of the CCD matrix, both differential signals providing feedback to the X- and Y-servo movers. Alternatively, the precise positioning in the XY plane may be obtained by using special rows and columns of pixels along the boundary of the photosensitive area of the CCD matrix, and corresponding special fluorescent marks located along the boundary of the information pages on the carrier. In this case, the differential signal of left and right columns controls the X-position, and the differential signal of upper and lower rows controls the Y-position. The control is realized by the feedback of the differential signal to the X-and Y-servo movers. The special marks provide the signal with the frequency different from the frequency band of the information signals. The readout rate of the special columns and rows can be higher than frame rate, and, hence, the time of precise positioning can be reduced.

To avoid discontinuity in motion, which is undesirable for high precise mechanical systems, and provide certain exposition time for imaging of a specific information page, the actuator with the objective lens moves uniformly together with the optical card with the same linear speed. When the specific information page is completely read, the actuator moves back to its non-shifted position and starts to read the next page. The speed of free pass back could be much faster than the speed of the optical card.

To obtain a readout data rate of about Gb/s, the information is read page by page in depth by refocusing the objective lens from layer to layer. During the reading of the information, the optical card moves uniformly. In order to keep the position of the objective lens above the specific column of pages, the actuator moves in the same direction and with the same speed. When the specific column is completely read, the actuator returns to the non-shifted position. The speed of free pass back could be much faster than the speed of the carrier (card).

The principles of uniform movement of the carrier to follow a specific information page can be applied to such a carrier as a rotating optical disc. In this case, pages in the disc are located along circular tracks, and the actuator with the objective lens moves together with the specific page during the exposition time and then returns back and reads the next page.

There is thus provided according to one aspect of the present invention, an apparatus for reproducing optical information stored in a fluorescent multilayer information carrier, in which the entire information field is formed by a plurality of sub-fields, the apparatus comprising:

(a) a light source generating a light beam of incident light having a predetermined frequency range selected so as to excite fluorescence in the information carrier and produce fluorescent information signals indicative of the information stored in the information carrier;

(b) a detector unit comprising a photosensitive matrix for detecting the fluorescent information signals and generating electrical output indicative thereof, which is to be processed to reproduce the stored information;

(c) an optical readout head designed to provide a predetermined geometry of the incident light beam to illuminate an area of the information carrier corresponding to a frame of the information sub-field, thereby enabling frame-by-frame imaging of the information sub-field onto the photosensitive matrix;

(d) a light directing assembly for directing the light beam generated by the light source towards the readout head and directing the information signals to the detector unit; and

(e) a drive system operable to provide relative displacement between the optical readout head and the information carrier along a predetermined pass, thereby enabling auto-focusing of the incident light beam from layer to layer and precise positioning of the optical readout head relative to the information caner within a plane parallel to the surface of the information carrier so as to provide a predetermined position of an image of each information sub-field on the photosensitive matrix.

According to another aspect of the present invention, there is provided, a method for reproducing optical information stored in a fluorescent multilayer information carrier, in which the entire information field is formed by a plurality of sub-fields, the method comprising the steps of:

(i) generating a light beam of incident light having a predetermined frequency range selected so as to excite fluorescence in the information carrier and produce fluorescent information signals indicative of the information stored in the information carrier;

(ii) directing the light beam through an optical readout head having an objective lens with an actuator and designed to provide a predetermined geometry of the incident light beam to illuminate an area of the information carrier corresponding to a frame of the information sub-field, and directing the information signals to a photosensitive matrix, thereby enabling frame-by-frame imaging of the information sub-field onto the photosensitive matrix;

(iii) detecting the information signals and generating electrical output indicative of the information stored in the information carrier;

(iv) selectively driving a movement of the objective lens with the actuator along an axis perpendicular to the surface of the carrier to focus the incident light from layer to layer, and selectively driving a relative displacement between the optical readout head and the information carrier along a predetermined pass to enable precise positioning of an image of each information sub-field on the photosensitive matrix, and to scan successive sub-fields.

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIG. 1 is a block diagram of an apparatus for reading in a fluorescent multilayer optical card according to one embodiment of the invention utilizing a red spectrum of incident light;

FIG. 2 is a block diagram of a reading apparatus according to another embodiment of the invention utilizing a green spectrum of incident light; and

FIG. 3 is an image of an information page (sub-field) and the results of decoding.

### DETAILED DESCRIPTION OF A PREFERRED EMBODIMENT

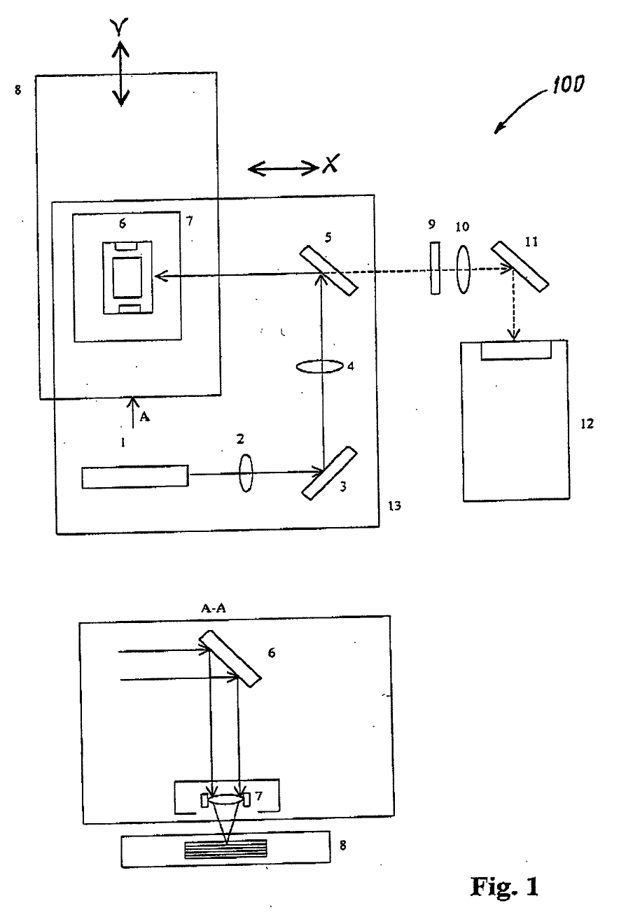

Referring to FIG. 1, there is illustrated an optical apparatus 100 according to one embodiment of the invention for reading information recorded in a nultilayer fluorescent card 8 (constituting a multilayer fluorescent information carrier). The apparatus 100 comprises such main constructional parts as a light source (diode laser) 1, an optical readout head 13, a light directing optical assembly LD, a detector unit DU, and a drive system. The drive system is operable to provide relative displacement between the card 8 and the readout bead 13 along X- and Y-axes, and provide relative displacement between an objective lens (focusing optics) of the readout head and the card along an optical axis of the focusing optics. In the present example, the optical readout head 13 is driven for movement along the X-axis, and the card is driven for movement along the Y-axis. It should, however, be noted that the card, as well as the readout head could be mounted for movement along both the X- and Y-axes.

The diode laser 1 emits a light beam having an elliptical form of its transverse section. The optical readout head 13 includes the following elements: a lens-collimator 2, a scanning mirror 3, a cylindrical lens 4, a dichroic mirror 5, a turning mirror 6, and a micro-objective with actuator 7. The main operational principles of all these elements are known per se, and therefore need not be specifically described, except to note the following. The lens-collimator 2 forms the parallel beam with minimal diversity. The scanning mirror 3 turns the light beam by 90° and, using an electromagnetic mover (not shown), provides the angular oscillation of the beam in the reflecting plane. The cylindrical lens 4 together with the micro-objective 7 form the strip-like shape of the light beam. The dichroic mirror 5 reflects the light beam towards the micro-objective 7 and filters back scattered light at the excitation frequency. The turning mirror 6 directs the light beam to the micro-objective with actuator 7. It should also be noted, although not specifically shown, that a mechanical mover is provided being associated with the multilayer fluorescent optical card 8. This mechanical mover, the drive associated with the readout head and the actuator associated with the micro-objective 7 constitute together the drive system, which is operable to provide wobbling of the micro-objective 7 along an axis perpendicular to the surface of the card 8, and the movement of the readout head and the card along two perpendicular axes within a plane parallel to the surface of the card.

The detector unit DU comprises a CCD matrix 12 (constituting a photosensitive matrix, which may alternatively be a CMOS matrix) connectable to a processor (not shown). The CCD matrix detects the fluorescent information signals coming from the optical card and generates electrical output indicative thereof. The detector unit DU is associated with the light directing assembly LD, which includes a filter 9 for filtering the exciting light, an imaging lens 10 that creates the image from infinity to the photosensitive surface of the CCD matrix 12, and a turning mirror 11 that directs the fluorescent emission from the readout head towards the detector unit DU.

The information is recorded in the card 8 in pages, each page presenting a pattern formed by a plurality of spaced-apart pits, and is read by scanning successive frames. To this end, the light beam impinging onto the card has the strip-like shape to illuminate an elongated area presenting the frame.

The above elements of the apparatus 100 form such main functional systems as an auto-focusing system, an excitation system, an auto-framing system, and a carrier motion system. This is implemented in the following manner:

Excitation system

The operation of the excitation system is aimed at providing a homogeneous excitation. For this purpose, the cylindrical lens 4 forms the strip-like geometry of the laser beam, thereby eliminating the interference picks in the intensity distribution. The angular oscillations of the turning mirror 3 provide scanning the page by strip-shape illuminated area, namely, the frame-by-frame excitation of the entire page. The scanning frequency ƒ relates to the frame rate F as follows: ƒ=F/N (N=1, 2, . . . ). This relation provides the synchronous operation of the CCD matrix 12, the auto-focusing system, and the excitation scanning system. This dynamic excitation system provides higher signal-to-noise ratio (SNR) and contrast, as compared to a static excitation where the whole page is excited simultaneously. Alternatively, the dynamic excitation of the illuminated area (frame) may take the form of a small spot, which scans the page in XY directions (within the plane parallel to the surface of the card). It could be realized by the angular scanning of both mirrors 3 and 6. In this case, the contrast and SNR would be higher than in the strip geometry based concept. Thus, the excitation system is formed by the laser, a beam-shaping optics (e.g., the cylindrical lens providing the strip geometry of the laser beam or any other suitable means providing an appropriate diameter of the laser beam to illuminate a small spot on the card), and the angular oscillating mirror(s) (e.g., mirror 3 in the case of strip-shaped laser beam and both mirrors 3 and 6 in the case of the circular laser beam).

Auto-framing system

The operation of the auto-framing (or imaging) system is aimed at providing the precise positioning of the optical readout head 13 relative to the card in the XY plane to match the position of a specific page to be read with high accuracy. This position should be such as to provide the location of the image of the card (illuminated area) symmetrically with respect to an axis of symmetry of the photosensitive area of the CCD matrix 12. The output signal from the CCD matrix is processed to generate the X,Y position error signal. This is implemented in the following manner. The X-error signal is a differential signal of the upper and lower halves of the photosensitive area of the CCD matrix, and the Y-error signal is the differential signal of the left and right halves of the photosensitive area. These differential signals provide feedback to X- and Y-axes drivers (e.g., servo-motors).

Alternatively, special group of pixels within the photosensitive area of the CCD matrix can be utilized being located at the left, right, upper and lower sides of the photosensitive area. In this case, the optical card is formed with corresponding fluorescent marks arranged along the contour of each page. This special servo information is stored in the form of modulation signals with the frequencies different from the spatial spectrum of the information signal. The differential signal from each pair of pixel group (left-right and upper-lower) controls the servo system. The readout rate of the servo registers can be much higher than the frame rate for the information field.

Thus, the auto-framing system is formed by the appropriate operation of the drive system, namely, the drive associated with the readout bead 13 (or the card, as the case may be) for moving the head in the X-Y-plane, and by processing the output of the CCD matrix (either utilizing the special group of pixels in the CCD matrix and the fluorescent marks in the card, or not).

Auto-focusing system

The operation of the auto-focusing system is aimed at focusing the micro-objective from layer to layer. The auto-focusing system is realized by wobbling of the actuator with the micro-objective 7 in the vertical direction (i.e., perpendicular to the surface of the card 8). According to one embodiment of the invention, the actor with micro-objective oscillates around a position of optimal focusing, which leads to the oscillation of an electrical signal from the CCD matrix at the same frequency. The oscillation produces a focusing error signal. The wobbling frequency ƒ is selected such that the frame rate F is equal to a multiple of the wobbling frequency, i.e., F=ƒ·N (N=1, 2, . . . ). The scheme of synchrony detection forms the servo-signal that controls the actuator of the micro-objective 7.

Alternatively, the special marks on the optical card can be utilized to be imaged onto the special group of pixels of the CCD matrix. In this case, the wobbling frequency ƒ has the following relation with the readout rate W of this special pixel group, i.e., W=N·ƒ(N=1, 2, . . . ), and can be much higher than frame rate F, the time of reaction of the auto-focusing system being thereby shorter than in the previous example. In other words, in this case of using the special group of pixels, the readout rate W of this group of pixels can be significantly higher than the frame rate F of the information part of the CCD matrix, and, hence, the focusing/refocusing from layer to layer is carried out faster.

Uniform motion of carrier

To avoid discontinuity in the motion of the carrier 8 and/or readout head 13, which is undesirable for high-precise mechanics, the present invention provides a novel principle of reading information. The carrier 8 moves uniformly with respect to the readout head 13 to sequentially align each of the successive pages with respect to the micro-objective 7. The actuator with the micro-objective 7 is involved in a periodical motion during which it follows the specific page for an exposition time, and then returns back and repeats the cycle with the next page.

The invented method provides the opportunity to read information with a very high data rate. For example, the CCD matrix has the frame rate of 2 KHz and the number of pixels is 2000×2000, and each information page has 1 million pits and the page size of 500 μm×500 μm. The actuator of the micro-objective 7 is capable of passing the distance of 500 μm during the time period of 5 ms. Thus, the average data rate is 200 Mb/s, or 20 times more than the data rate of the conventional DVD format, and is sufficient to read an uncompressible high-resolution movie.

A much higher data rate can be obtained by reading the information page by page in depth (i.e., pages of the successive layers). In this case, the pages from different layers are combined in columns and information is read page by page in depth by refocusing the objective lens from layer to layer. During the reading of the specific column, the optical card is moving towards the next column. To stay at the fixed coordinate above certain column, the actuator with the objective moves in the same direction in order to compensate the motion of the carrier (card 8).

The following is the numerical example of the above. The optical card 8 has 50 layers, with the distance between each two adjacent layers being about 20 μm. The number of pixels per page is equal to 10⁶ and the page size is 500 μm×500 μm. The CCD matrix 12 has the frame rate of 2 KHz and 2000×2000 pixels. The refocusing time is 1 ms. The time of reading one column is 50 ms. During this time, the card S shifts by 500 μm, and, when the certain column is completely read, the actuator moves and takes the non-shifted position with respect to the first layer in the column. The time needed to return the actuator to the non-shifted position is 5 ms. Thereafter, the reading of the next column is started. The average readout data rate is of about 1 Gb/s.

It should be noted that the invented method can be applied for reading information from a rotating disc as well. In this case, information pages are located along circular tracks and the actuator following the certain page moves in the direction of the disc rotation.

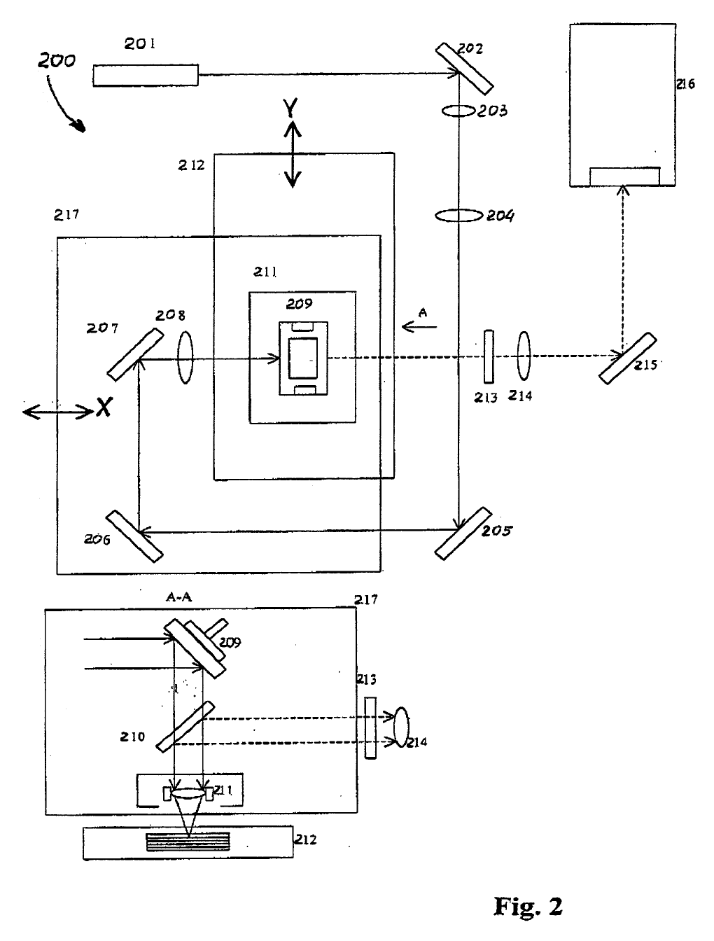

In the example of FIG. 1, the light emitted by the diode laser lies within the red spectral region, λ=650 nm. Turning now to FIG. 2, there is illustrated an apparatus 200 according to another embodiment of the invention for reading information stored in an information carrier (card) 212. Here, a diode laser 201 emits light in the green spectral region, i.e., λ=532 nm. The emitted light is directed towards an optical readout head 217 by turning mirrors 202 and 205, first and second lens collimators 203 and 204, and is directed from the readout head 217 towards a detector unit DU comprising a CCD matrix 216 through a spectral filter 213, an imaging lens 214 and a turning mirror 215.

The optical readout head 217 comprises turning mirrors 206 and 207, a cylindrical lens 208, a scanning mirror 209, a dichroic mirror 210, and a movable micro-objective 211, all those elements being mounted on a movable platform.

In the present example, the laser diode has the power of 10 mW. The collimator (first and second lens-collimators 203 and 204) has the focal length of 4.5 mm and numerical aperture of 0.5, and forms a parallel beam with a transverse section of 4.5×1 mm. The scanning minor has the wobbling frequency of 50 HZ and amplitude of scanning of ±2°. The micro-objective 211 has the focal length of 4.5 mm and the numerical aperture NA equal to 0.5. The micro-objective 211 is based on the actuator that has the amplitude of shift of ±0.8 mm with the accuracy of 0.5 μm, sensitivity of 1.6 mm/V, and the resonant frequency of 2 Hz with the band of oscillations of 1 KHz. The micro-objective 211 provides reading of the 230×320 μm field of view of the CCD matrix 216. The movable platform supporting the readout bead 217 is capable of shifting by a distance of 25 mm with the accuracy of 30 μm. The optical filter 213 provides discrimination of exciting light by factor of 10⁴ and with the coefficient of transparency for fluorescence 0.4. The information is stored in the form of pages with pits having the size of 1 μm×1 μm and the distance between the adjacent pits of 2 μm. The page with size 300 μm×200 μm is imaged on the photo-sensitive area of the CCD matrix having 582×752 pixels, with the pixel size of 8 μm×9 μm. The oversampling is 25 pixels per pit.

Similarly to the example of FIG. 1, the apparatus 200 includes an excitation system, an imaging (auto-framing) system, an auto-focusing system, and servo mechanisms for scanning the card 212. The system of excitation is formed by the laser diode 201, the collimator (first and second lens-collimators 203 and 204), and the scanning mirror 209.

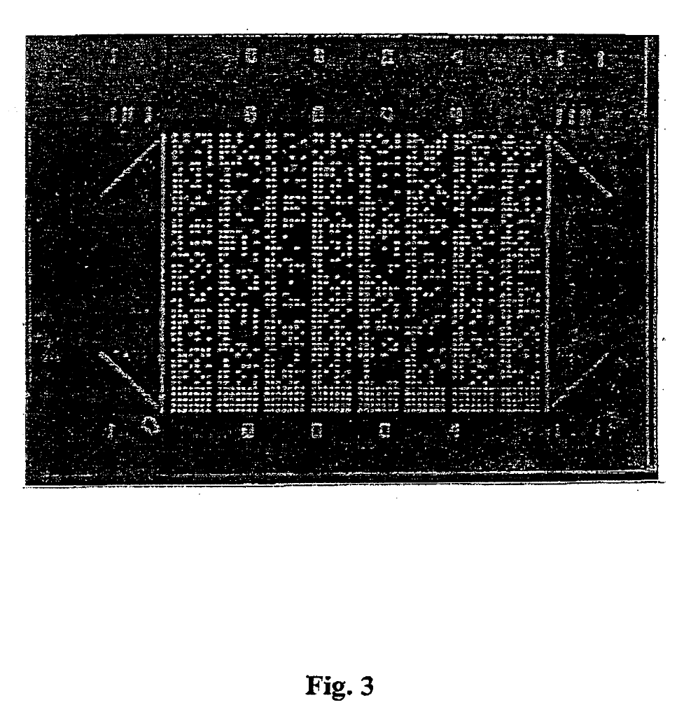

FIG. 3 illustrates an example of the image of an information page with pits, and the result of decoding the text encoded by ASCII code.

Those skilled in the art will readily appreciate that various modifications and changes can be applied to the preferred embodiment of the invention as herein before exemplified without departing from its scope defined in and by the appended claims.

1. An apparatus for reproducing optical information stored in a fluorescent multilayer information carrier, in which the entire information field is formed by a plurality of sub-fields, the apparatus comprising:
(a) a light source generating a light beam of incident light having predetermined frequency range selected so as to excite fluorescence in the information carrier and produce fluorescent information signals indicative of the information stored in the information carrier;
(b) a detector unit comprising a photosensitive matrix for detecting the fluorescent information signals and generating electrical output indicative thereof, which is to be processed to reproduce the stored information;
(c) an optical readout head designed to provide a predetermined geometry of the incident light beam to illuminate an area of the information carrier corresponding to a frame of the information sub-field, thereby enabling frame-by-frame imaging of the information sub-field onto the photosensitive matrix;
(d) a light directing assembly for directing the light beam generated by the light source towards the readout bead and directing the information signals to the detector unit; and
(e) a drive system operable to provide relative displacement between the optical readout head and the information carrier along a predetermined pass, thereby enabling auto-focusing of the incident light beam from layer to layer and precise positioning of the optical readout head relative to the information carrier within a plane parallel to the surface of the information carrier so as to provide a predetermined position of an image of each information sub-field on the photosensitive matrix.

2. The apparatus according to claim 1, wherein the optical readout head comprises an objective lens with an actuator operable by the drive system to provide wobbling of the objective lens along an axis perpendicular to the surface of the information carrier with a predetermined wobbling frequency.

3. The apparatus according to claim 2, wherein the drive system is operable to provide oscillation of the objective lens around a position of optimal focusing with said predetermined wobbling frequency, thereby providing oscillation of the electrical output at the same frequency, said wobbling frequency ƒ being selected such that a frame rate F is equal to multiple of the wobbling frequency: F=N·ƒ, wherein N=1, 2, . . . .

4. The apparatus according to claim 1, wherein said photosensitive matrix is a CCD.

5. The apparatus aiding to claim 1, wherein the photosensitive matrix is a CMOS.

6. The apparatus according to claim 2, wherein special fluorescent marks are provided within each information sub-field to be imaged on a special group of pixels of the photosensitive matrix during the wobbling of the objective lens, said special fluorescent marks providing the fluorescent excitation of a frequency band different to the frequency band of the information signals, the wobbling frequency ƒ being selected to satisfy the following condition: W=N·ƒ(N=1, 2 . . . ), wherein W is a readout rate of said special group of pixels, and to be higher than a frame rate F.

7. The apparatus according to claim 1, wherein said predetermined position of the image of the information sub-field on the photosensitive matrix is such that said image is symmetrical with respect to an axis of symmetry of the photosensitive area.

8. The apparatus according to claim 7, wherein a first error signal corresponding to the first position of the image along a first axis parallel to the surface of the carrier is a first differential signal of the electrical signals generated in upper and lower halves of the photosensitive matrix, and a second error signal corresponding to the second position of the image along the second axis parallel to the surface of the carrier and perpendicular to the first axis is a second differential signal of the electrical signals generated in right and left halves of the photosensitive matrix, the first and second differential signals providing feedback to the drive system.

9. The apparatus according to claim 7, wherein the information sub-fields are arranged in rows and columns within the multilayer information carrier, and the information carrier is provided with special fluorescent marks located along a boundary of the information sub-field and providing the fluorescent excitation of a frequency band different to the frequency band of the information signals, the relative position along a first axis parallel to the surface of the carrier being controlled by detection of a first differential signal associated with left and right columns, and the relative position along a second axis parallel to the surface of the carrier and perpendicular to the first axis being controlled by detection of a second differential signal associated with upper and lower rows, the first and second differential signals providing feedback to the drive system.

10. The apparatus according to claim 9, wherein a readout rate of the special columns and rows is higher than a frame rate, thereby reducing a time of the precise positioning.

11. The apparatus according to claim 2, wherein the drive assembly is operable to provide uniform motion of the objective lens with the actuator and of the information carrier with the same linear speed when reading the information within the information sub-field, and to provide a back-and-forward motion of the objective lens with the actuator within a plane parallel to the surface of the carrier for sequential reading of the successive sub-fields.

12. The apparatus according to claim 11, wherein a speed of the back-and-forward motion is much higher than the speed of the carrier.

13. A method for reproducing optical information stored in a fluorescent multilayer information carrier, in which the entire information field is formed by a plurality of sub-fields, the method comprising the steps of:
(i) generating a light beam of incident light having a predetermined frequency range selected so as to excite fluorescence in the information carrier and produce
fluorescent information signals indicative of the information stored in the information corner;
(ii) directing the light beam through an optical readout head having an objective lens with all actuator and designed to provide a predetermined geometry of the incident light beam to illuminate an area of the information carrier corresponding to a frame of the information sub-field, and directing the information signals to a photosensitive matrix, thereby enabling frame-by-frame imaging of the information sub-field onto the photosensitive matrix;
(iii) detecting the information signals and generating electrical output indicative of the information stored in the information carrier;
(iv) selectively driving a movement of the objective lens with the actuator along an axis perpendicular to the surface of the carrier to focus the incident light from layer to layer, and selectively driving relative displacement between the optical readout head and the information carrier along a predetermined pass to enable precise positioning of an image of each information sub-field on the photosensitive matrix, and to scan successive sub-fields.

14. The method according to claim 13, wherein the objective lens with the actuator of the optical readout head is driven to provide wobbling of the objective lens along an axis perpendicular to the surface of the information carrier with a predetermined wobbling frequency.

15. The method according to claim 14, wherein said wobbling provides oscillation of the objective lens around a position of optimal focusing, thereby providing oscillation of the electrical output with the frequency equal to the wobbling frequency, said wobbling frequency ƒ being selected such that a frame rate F is equal to multiple of the wobbling frequency: F=N·ƒ, wherein, N=1, 2, . . . .

16. The method according to claim 14, wherein during the wobbling of the objective lens special fluorescent marks provided within each information sub-field are imaged on a special group of pixels of the photosensitive matrix, said special fluorescent marks providing the fluorescent excitation of a frequency band different to the frequency band of the information signals, the wobbling frequency ƒ being selected to satisfy the following condition: W=N·ƒ(N=1, 2 . . . ), wherein W is a readout rate of said special group of pixels, and to be much higher than a frame rate F.

17. The method according to claim 13, wherein said predetermined position of the image of the information sub-field on the photosensitive matrix is such that said image is symmetrical with respect to an axis of symmetry of the photosensitive area.

18. The method according to claim 16, wherein during the wobbling of the objective lens, first and second error signals corresponding to the position of said image along first and second axes are generated by the photosensitive matrix, the first and second axes being perpendicular to each other and parallel to the surface of the carrier, the first error signal being a first differential signal of the electrical signals generated in upper and lower halves of the photosensitive matrix, and the second error signal being a second differential signal of the electrical signals generated in right and left halves of the photosensitive matrix, the first and second differential signals providing feedback for driving the movement of readout head within a plane parallel to the surface of the carrier.

19. The method according to claim 16, wherein the information sub-fields are arranged in rows and columns within the multilayer information carrier, and the information carrier is provided with special fluorescent marks located along a boundary of the information sub-field and providing the fluorescent excitation of a frequency band different to the frequency band of the information signals, during the wobbling of the objective lens first and second error signals corresponding to the position of said image along first and second axes being generated by the photosensitive matrix, the first and second axes being perpendicular to each other and parallel to the surface of the carrier, the first error signal being a first differential signal associated with left and right columns, and the second error signal being a second differential signal associated with upper and lower rows, the first and second differential signals providing feedback for driving the movement of the readout head in the plane parallel to the surface of the information carrier.

20. The method according to claim 19, wherein a readout rate of the special columns and rows is higher than a frame rate, thereby reducing a time of the precise positioning.

21. The method according to claim 13, wherein the objective lens with the actuator and of the information carrier are driven with the same linear speed when scanning each of the information sub-fields, and the objective lens with the actuator is driven for a back-and-forward motion within a plane parallel to the surface of the carrier to provide sequential scanning of the successive sub-fields.
